(19) United States
(12) Patent Application Publication
(10) Pub. No.: US 2021/0384090 A1
(43) Pub. Date: Dec. 9, 2021

(54) AUXILIARY WAFER, PREPARATION METHOD OF AUXILIARY WAFER, AND SEMICONDUCTOR PRODUCTION PROCESS

(71) Applicant: CHANGXIN MEMORY TECHNOLOGIES, INC., Hefei City (CN)

(72) Inventor: Shuai GUO, Hefei (CN)

(73) Assignee: CHANGXIN MEMORY TECHNOLOGIES, INC., Hefei City (CN)

(21) Appl. No.: 17/411,700

(22) Filed: Aug. 25, 2021

Related U.S. Application Data
(63) Continuation of application No. PCT/CN2021/095595, filed on May 24, 2021.

(30) Foreign Application Priority Data
Jun. 8, 2020 (CN) 202010513650.1

(51) Int. Cl. H01L 21/66; H01L 21/67; H01L 21/311

(52) U.S. Cl. CPC H01L 22/34; H01L 21/31105; H01L 21/67276

(57) ABSTRACT

Provided are an auxiliary wafer, a preparation method of the auxiliary wafer, and a semiconductor production process. The preparation method includes: providing an initial wafer; forming a protective film on a surface of the initial wafer, wherein a material of the protective film comprises aluminum oxide of a low-temperature phase; and carrying out an annealing process on the protective film to transform at least part of aluminum oxide from the low-temperature phase into a high-temperature phase to form a protective layer.

### CROSS-REFERENCE TO RELATED APPLICATIONS

The present application is a continuation of International Patent Application No. PCT/CN2021/095595, filed on May 24, 2021, which claims priority to Chinese Patent Application No. 202010513650.1, filed on Jun. 8, 2020. The entire contents of the above-referenced patent applications are incorporated herein by reference.

### TECHNICAL FIELD

Embodiments of the present application relate to the field of semiconductors, and in particular to an auxiliary wafer, a preparation method of the auxiliary wafer, and a semiconductor production process.

### BACKGROUND

In a machine process, in order to monitor a wafer production process, an auxiliary wafer is usually required to monitor or maintain the effectiveness of the production process. The same product process will be performed on surfaces of both the auxiliary wafer and a product wafer. In order to realize the cycle use of the auxiliary wafer, the auxiliary wafer is usually pre-processed before being placed in a machine, so as to form a protective film on a surface, to be processed, of the auxiliary wafer. The protective film can protect the auxiliary wafer during the removal of other materials from a side of the auxiliary wafer away from the protective film, thereby avoiding damage to the auxiliary wafer caused by the removal process and further ensuring the cycle use of the auxiliary wafer.

The existing protective film has poor durability and is easy to damage, and the auxiliary wafer has a limited service life and can be reused few times, thus resulting in a high cost for the semiconductor production process.

### SUMMARY

Some embodiments of the present application provide an auxiliary wafer, a preparation method of the auxiliary wafer, and a semiconductor production process, which are beneficial to increasing the number of reuse cycles of the auxiliary wafer.

In order to solve the above problem, some embodiments of the present application provide a preparation method of an auxiliary wafer, including: providing an initial wafer; forming a protective film on a surface of the initial wafer, wherein a material of the protective film includes aluminum oxide of a low-temperature phase; and carrying out an annealing process on the protective film to transform at least part of aluminum oxide from the low-temperature phase into a high-temperature phase to form a protective layer.

Correspondingly, some embodiments of the present application further provide an auxiliary wafer, including: an initial wafer and a protective layer on a surface of the initial wafer, wherein a material of the protective layer includes aluminum oxide, and at least part of the aluminum oxide presents a high-temperature phase.

Correspondingly, some embodiments of the present application further provide a semiconductor production process, including: providing a product wafer and the above-mentioned auxiliary wafer; step A: performing the same process on the product wafer and the auxiliary wafer, so as to form a functional layer on the surface of each of the product wafer and the auxiliary wafer; and step B: removing the functional layer from the surface of the auxiliary wafer.

### BRIEF DESCRIPTION OF DRAWINGS

One or more embodiments are exemplified by pictures in the corresponding drawings. These exemplified descriptions do not constitute a limitation on the embodiments. Elements with the same reference numerals in the drawings are denoted as similar elements. Unless otherwise stated, the figures in the accompanying drawings do not constitute a scale limitation.

FIG. 1 and FIG. 2 are schematic cross-sectional structural diagrams corresponding to each step of a preparation method of an auxiliary wafer according to an embodiment of the present application; and

FIG. 3 and FIG. 4 are schematic cross-sectional structural diagrams corresponding to each step of a semiconductor process according to an embodiment of the present application.

### DESCRIPTION OF EMBODIMENTS

In the semiconductor industry, a wafer used to monitor the process stability between batches is called control wafer, and a wafer used to maintain the process stability of a single batch is called dummy wafer. The main function of the control wafer is to monitor the stability and repeatability of a machine (including a furnace tube and a chamber machine) through implementation of a process; the main function of the dummy wafer is to stabilize an airflow and balance an internal temperature of the machine by filling a vacant position, so as to maintain the stability and uniformity of the process.

Specifically, in a furnace tube process, in order to monitor whether a furnace tube machine is stable, a control wafer and a product wafer need to be placed together in the machine for the process to compare and observe the process quality; in addition, in order to maintain stable characteristics such as stable airflow distribution in the furnace tube, when the number of product wafers in the furnace tube is insufficient, auxiliary wafers need to be added make a supplement. When the chamber machine is warmed up, a certain number of auxiliary wafers are usually required for operation.

In the preparation method of an auxiliary wafer provided by the embodiments of the present application, low-temperature phase aluminum oxide is used as a raw material and transformed into a high-temperature phase through an annealing process. Compared with low-temperature phase aluminum oxide, high-temperature phase aluminum oxide has higher crystal structure stability and lower reactivity. In this way, it is beneficial to preventing aluminum oxide from reacting with an etchant in a removal process, reducing a damage caused by the etchant to a protective layer, and increasing the number of reuse cycles of the protective layer.

The auxiliary wafer of the present application includes a control wafer and a dummy wafer. The control wafer can be placed in a machine together with a product wafer for process processing, or it can be processed separately. It should be noted that although the dummy wafer does not need to be processed, a surface of the dummy wafer may still be contaminated. A source of contamination includes molecular contaminants carried by a heat flow during warming up. Therefore, the dummy wafer needs to be cleaned after use. In order to avoid damage to the dummy wafer by the cleaning process, a protective layer of a certain thickness can be formed on the surface of the dummy wafer so that the dummy wafer can be reused.

In order to make the objectives, the technical solutions, and the advantages of the embodiments of the present application clearer, the detailed description of the embodiments of the present application is given below in combination with the accompanying drawings. The ordinary skills in the art can understand that many technical details are provided in the embodiments of the present application so as to make the readers better understand the present application. However, even if these technical details are not provided and based on a variety of variations and modifications of the following embodiments, the technical solutions sought for protection in the present application can also be realized.

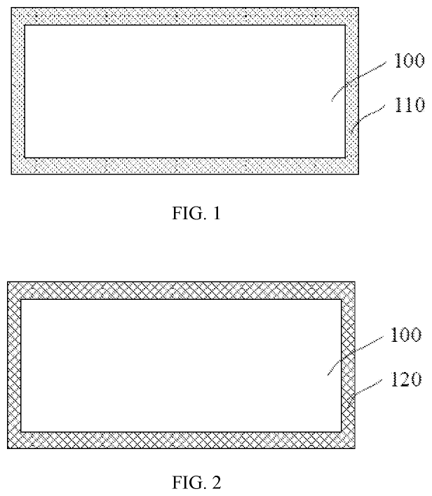

FIG. 1 and FIG. 2 are schematic cross-sectional structural diagrams corresponding to each step of a preparation method of an auxiliary wafer according to an embodiment of the present application.

Referring to FIG. 1, an initial wafer 100 is provided, and a protective film 110 is formed on a surface of the initial wafer 100. A material of the protective film 110 includes aluminum oxide of a low-temperature phase.

In this embodiment, the initial wafer 100 has the same size as a product wafer. In this way, the product wafer can be directly used and processed to form an auxiliary wafer and the initial wafer 100 does not need to be prepared separately, so that the initial wafer 100 can be obtained easily.

In other embodiments, a size of the initial wafer is adjusted according to a thickness of a protective layer to be formed, so that a size of the auxiliary wafer after the formation of the protective layer is the same as a size of the product wafer. In this way, it is beneficial to ensuring that a size of a product structure formed on the surface of the auxiliary wafer is the same as a size of a product structure formed on a surface of the product wafer, so that the auxiliary wafer can more accurately monitor whether the product structure formed on the surface of the product wafer meets a predetermined requirement.

In this embodiment, a precursor is used to form the protective film 110 on the surface of the initial wafer 100, and the precursor includes trimethylaluminum and ozone; in other embodiments, the precursor includes aluminum trichloride and ozone.

For example, the trimethylaluminum is carried by a carrier gas, so that the trimethylaluminum can be fed into a reaction chamber together with ozone. Compared with solid trimethylaluminum, the trimethylaluminum carried by the carrier gas has a lower density and can fully react with gaseous ozone. In this way, it is beneficial to ensuring the full utilization of the precursor. Moreover, since the trimethylaluminum is a toxic substance, the full reaction of the trimethylaluminum is beneficial to reducing the cost of a subsequent pollution treatment, thereby reducing the overall process cost.

In this embodiment, a flow rate of the carrier gas is within a range of 100 sccm to 400 sccm, and can be, for example, 200 sccm, 250 sccm, or 300 sccm. The flow rate of the carrier gas in this range is beneficial to ensuring that the trimethylaluminum carried by the carrier gas can fully react with ozone, and there is little or no residue after the reaction; in addition, it is beneficial to avoiding the case that excessive trimethylaluminum reacts with ozone at the same time to release excessive heat, thereby avoiding problems such as an explosion that may be caused by excessive heat release, and improving the safety of the production process.

In this embodiment, when the precursor is used to form the protective film 110, a temperature condition in the reaction chamber is controlled within a range of 200° C. to 600° C., and can be, for example, 300° C., 400° C., or 500° C. In this way, it is beneficial to avoiding a trimethylaluminum explosion caused by an excessively high temperature in the reaction chamber, thereby ensuring the safety of the production process; in addition, it is beneficial to dehydration of the initially formed aluminum oxide to a certain extent, so that the aluminum oxide can form a low-temperature phase aluminum oxide with a relatively stable crystal structure, such as ρ-AL₂O₃, χ-AL₂O₃, η-AL₂O₃ or γ-AL₂O₃, and a molecular formula of the low-temperature phase aluminum oxide can be written as AL₂O₃.nH₂0, where 0<n<0.6.

Since the aluminum oxide of the low-temperature phase shrinks to a certain extent during the annealing process, that is, a molecular group size of the aluminum oxide of the high-temperature phase is less than that of the aluminum oxide of the low-temperature phase. Therefore, after the protective film 110 is transformed into a protective layer, a thickness of the protective layer in a direction perpendicular to the surface of the initial wafer 100 is less than that of the protective film 110. That is, during the formation of the initial protective film 110, the thickness of the protective film 110 should be greater than a required thickness of the protective layer.

In this embodiment, the protective film 110 covers the entire surface of the initial wafer 100, for example, including side, upper and lower surfaces of the initial wafer 100, thus ensuring the protective effect of the protective layer formed during the annealing process of the protective film 110. In other embodiments, the protective film covers part of the surface of the initial wafer; for example, the protective film may only cover the upper surface.

Referring to FIG. 2, after formation of the protective film 110 (referring to FIG. 1), the protective film 110 is heat-treated using a spike annealing process to form a protective layer 120.

Compared with a uniform-temperature annealing process, the peak annealing process requires a shorter annealing time while realizing the effective dehydration of the aluminum oxide of the low-temperature phase, which is beneficial to reducing the process time. In this way, while the protective film 110 is transformed into the protective layer 120, heat accumulated in a furnace tube and the reaction chamber can be reduced, thereby avoiding accidents such as combustion and explosion caused by excessive heat.

In this embodiment, a peak temperature of the spike annealing process is greater than 900° C. In this way, it is beneficial to transformation of the aluminum oxide in the protective layer 120 into completely dehydrated α-AL₂O₃, commonly known as corundum. As the most stable one in crystal structures of aluminum oxide currently found, α-AL₂O₃ has a hardness second only to diamond and is not easily damaged. In addition, α-AL₂O₃ is insoluble in strong acid and can better protect the initial wafer 100.

In this embodiment, after the formation of the protective layer 120, a functional layer is formed on the protective layer 120; for example, the functional layer may be a structural layer or a material layer realized by deposition, etching, printing, and the like. For the same etching process, an etching selection ratio of the functional layer to the initial wafer 100 is less than an etching selection ratio of the functional layer to the protective layer 120. In this way, it is beneficial to ensuring the protective effect of the protective layer 120.

In this embodiment, aluminum oxide is transformed from a low-temperature phase to a high-temperature phase, so that the aluminum oxide has a more stable crystal phase structure and lower activity. In this way, it is beneficial to reducing a damage to the aluminum oxide caused by the removal process during the removal of a dielectric material from the surface of the auxiliary wafer. For example, taking a monitoring wafer as an example, the Al₂O₃ after the high-temperature annealing is extremely resistant to corrosion by a HF/HNO₃ mixed solution, with an etching rate of almost zero. In the case of few reuse cycles, the protective layer can be directly put into the furnace tube or the reaction chamber to be reused as a monitor wafer without a need of pre-processes for the formation of a protective layer or performance confirmation. However, non-annealed Al₂O₃ or a dielectric material with a high dielectric constant can be corroded by the HF/HNO₃ mixed solution at a very high etching rate, and its performance needs to be confirmed after a few reuse cycles so that the protective layer still has better protection performance.

The above-mentioned solution can effectively increase the number of reuse cycles of the protective layer and the auxiliary wafer. Compared with ordinary 10 to 30 reuse cycles, the number of reuse cycles of the technical solution disclosed in the present application can reach 300. In this way, the use cost of a control wafer (including a monitor wafer and a fill wafers) and/or a dummy wafer can be effectively reduced.

Correspondingly, an embodiment of the present application further provides an auxiliary wafer, which can be made by using the above-mentioned preparation method of an auxiliary wafer.

Referring to FIG. 2, the auxiliary wafer includes: an initial wafer 100 and a protective layer 120 on a surface of the initial wafer 100. A material of the protective layer 120 includes aluminum oxide, and phases of the aluminum oxide include a high-temperature phase.

In this embodiment, the protective layer 120 covers the entire surface of the initial wafer 100, for example, including side, upper and lower surfaces of the initial wafer 100; in other embodiments, the protective layer covers part of the surface of the initial wafer, for example, the protective layer may only cover the upper surface. If the protective layer 120 only covers the upper surface of the initial wafer 100 and when a mixed acid is used for cleaning, the mixed acid will corrode an area of the initial wafer 100 which is not covered by the protective layer 120. However, compared with the prior art, this solution can still increase the number of reuse cycles of the auxiliary wafer.

In this embodiment, the protective layer 120 at any position on the surface of the initial wafer 100 is made of aluminum oxide of a high-temperature phase; in other embodiments, only the protective layer on the upper surface (i.e., the surface subjected to the process) of the initial wafer is made of aluminum oxide of the high-temperature phase, and the protective layer at the remaining positions is made of aluminum oxide of a low-temperature phase. Alternatively, the protective layer includes a first protective layer in contact with the surface of the initial wafer and a second protective layer away from the surface of the initial wafer. The first protective layer is made of aluminum oxide of the low-temperature phase, and the second protective layer is made of aluminum oxide of the high-temperature phase.

In this embodiment, in a direction perpendicular to the surface of the initial wafer 100, the thickness of the protective layer 120 is greater than or equal to 2 nm. In this way, it is beneficial to ensuring that the protective layer 120 has a large number of reuse cycles. It should be noted that the number of reuse cycles of the protective layer 120 is not only related to the thickness of the protective layer 120, but also related to process steps in a semiconductor production process. For example, in addition to the corrosion of the HF/HNO₃ mixed solution in the removal process, during other process steps, especially during a heat treatment step, a high temperature will pass through the protective layer 120 and affect the performance of the initial wafer 100.

For example, when the initial wafer 100 contains a conductive material placed in a silicon through hole, multiple heat treatments may cause the conductive material to swell and deform, thereby causing uneven stress at various positions of the initial wafer 100, and even causing cracks and other deformation features on the initial wafer 100. Therefore, when considering the thickness of the protective layer 120, in addition to the process time of the annealing process (annealing for a long time may have risks such as an explosion) and the required number of reuse cycles, the durability (i.e., the number of processes that the initial wafer 100 can go through) of the initial wafer 100 also needs to be considered, thereby ensuring that the performance of the initial wafer 100 meets the requirement during the reuse cycles and further ensuring that test results of the final functional layer are correct.

In this embodiment, the material of the protective layer 120 includes α-AL₂O₃, commonly known as corundum.

In this embodiment, aluminum oxide of the high-temperature phase is used as the material of the protective layer, so that the protective layer has relatively high damage resistance. When the initial wafer has not been degraded or damaged, it can be put into the furnace tube or the reaction chamber for multiple times to serve as a monitor wafer and/or a fill wafer. In this way, the auxiliary wafer can be reused for more times and the use cost of the control wafer and/or the dummy wafer can be effectively reduced.

Correspondingly, an embodiment of the present application further provides a semiconductor production process for application of the above-mentioned auxiliary wafer.

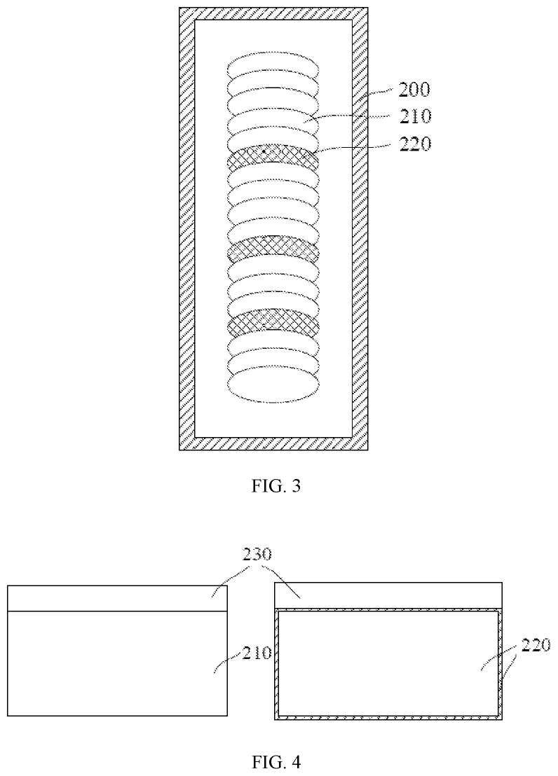

FIG. 3 to FIG. 4 are schematic cross-sectional structural diagrams corresponding to each step of a semiconductor process according to an embodiment of the present application.

Referring to FIG. 3, a product wafer 210 and the aforementioned auxiliary wafer 220 are provided. The product wafer 210 and the auxiliary wafer 220 are placed in a furnace tube 200 for the same production process to form the same required functional layer.

Referring to FIG. 4, Step A: the same production process is carried out on the product wafer 210 and the auxiliary wafer 220. The production process includes deposition, etching, annealing, and printing to form a functional layer 230 on a surface of each of the product wafer 210 and the auxiliary wafer 220.

In this embodiment, the product wafer 210 and the auxiliary wafer 220 have the same size; in other embodiments, the size of an initial wafer in the auxiliary wafer is the same as the size of the product wafer.

In this embodiment, after the formation of the functional layer 230, at least one auxiliary wafer 220 is taken out of the furnace tube, or at least one auxiliary wafer 220 is taken out of the reaction chamber, and a thickness of the functional layer 230 above the auxiliary wafer 220 is measured to preliminarily determine whether the functional layer 230 meets a predetermined requirement. If the requirement is met, the functional layer 230 on the surface of the auxiliary wafer 220 is removed; if the requirement is not met, the type and cause of a defect are analyzed according to the functional layer 230 on the surface of the auxiliary wafer 220.

In addition, after the thickness of the functional layer 230 meets the predetermined requirement, the functional layer 230 may be further subjected to performance testing, such as electrical performance testing; if the performance of the functional layer 230 meets the predetermined requirement, the functional layer 230 is removed.

Step B: the functional layer 230 on the surface of the auxiliary wafer 220 is removed.

The functional layer 230 is usually removed by a HF/HNO₃ mixed solution to ensure that the functional layer 230 can be completely removed. Since α-AL₂O₃ has strong stability to acid, is resistant to corrosion by the HF/HNO₃ mixed solution, and has relatively high hardness, the damage caused by a single removal process to α-AL₂O₃ is limited, and if the damage does not affect the performance of the auxiliary wafer 220, the remaining auxiliary wafer 220 can be reused. That is to say, in the semiconductor production process, the above steps A and B can be performed cyclically until the performance of the auxiliary wafer 220 does not meet the requirement, and the expression “the performance of the auxiliary wafer does not meet the requirement” means that the performance of either the protective layer or the initial wafer no longer meets the process requirement.

According to the testing, α-AL₂O₃ with a thickness of 2 nm can withstand damages caused by about 300 times of removal process, and its performance is greatly improved compared with the performance of the existing protective layer.

In this embodiment, a semiconductor production process is provided, and the above-mentioned auxiliary wafer is applied to the semiconductor production process, so that the auxiliary wafer can be reused for multiple times, and the process cost is reduced.

The ordinary skills in the art can understand that the implementations described above are particular embodiments for implementing the present application. In practical uses, various changes in forms and details may be made to the implementations without departing from the spirit and scope of the present application. Any person skilled in the art may make their own changes and modifications without departing from the spirit and scope of the present application. Therefore, the protection scope of the present application shall be subject to the protection scope of the claims.

What is claimed is:

1. A preparation method of an auxiliary wafer, comprising:
providing an initial wafer;
forming a protective film on a surface of the initial wafer, wherein a material of the protective film comprises aluminum oxide of a low-temperature phase; and
carrying out an annealing process on the protective film to transform at least part of aluminum oxide from the low-temperature phase into a high-temperature phase to form a protective layer.

2. The preparation method according to claim 1, wherein the forming a protective film on a surface of the initial wafer comprises:
forming the protective film on the surface of the initial wafer using a precursor, wherein the precursor comprises trimethylaluminum and ozone, or the precursor comprises aluminum trichloride and ozone.

3. The preparation method according to claim 2, wherein a carrier gas is used to carry the trimethylaluminum, and a flow rate of the carrier gas is within a range of 100 sccm to 400 sccm.

4. The preparation method according to claim 2, wherein the protective film is formed from the precursor at a temperature in a range of 200° C. to 600° C.

5. The preparation method according to claim 2, wherein the annealing process comprises spike annealing, and the spike annealing is carried out at a temperature greater than 900° C.

6. The preparation method according to claim 1, wherein aluminum oxide of the high-temperature phase comprises α-AL₂O₃.

7. The preparation method according to claim 1, further comprising:
forming a functional layer on the protective layer, wherein for the same etching process, an etching selection ratio of the functional layer to the initial wafer is less than an etching selection ratio of the functional layer to the protective layer.

8. An auxiliary wafer, comprising:
an initial wafer and a protective layer on a surface of the initial wafer, wherein the material of the protective layer comprises aluminum oxide, and at least part of the aluminum oxide presents a high-temperature phase.

9. The auxiliary wafer according to claim 8, wherein in a direction perpendicular to the surface of the initial wafer, a thickness of the protective layer is greater than or equal to 2 nm.

10. The auxiliary wafer according to claim 8, wherein the material of the protective layer comprises α-AL₂O₃.

11. A semiconductor production process, comprising:
providing a product wafer and the auxiliary wafer according to claims 8;
step A: performing the same production process on the product wafer and the auxiliary wafer, so as to form a functional layer on the surface of each of the product wafer and the auxiliary wafer; and
step B: removing the functional layer from the surface of the auxiliary wafer.

12. The semiconductor production process according to claim 11, wherein the step A and the step B are executed cyclically.

13. The semiconductor production process according to claim 11, wherein in a direction perpendicular to the surface of the initial wafer, a thickness of the protective layer is greater than or equal to 2 nm.

14. The semiconductor production process according to claim 11, wherein the material of the protective layer comprises α-AL₂O₃.
